(19) United States
(12) Patent Application Publication
(10) Pub. No.: US 2009/0173378 A1
(43) Pub. Date: Jul. 9, 2009

(54) Charge Separation Polymers

(76) Inventors: Paul Leslie Burn, Oxford (GB); Bimlesh Lochab, Oxford (GB)

Correspondence Address: NIXON & VANDERHYE, PC, 901 NORTH GLEBE ROAD, 11TH FLOOR, ARLINGTON, VA, 22203, US

(21) Appl. No.: 11/989,611

(22) PCT Filed: Jul. 25, 2006
(86) PCT No.: PCT/GB2006/002781

§ 371 Date: Oct. 29, 2008

(30) Foreign Application Priority Data
Jul. 29, 2005 (GB) 0515710.2

(51) Int. Cl. H01L 31/00; C08G 79/08; C08G 65/00

(52) U.S. Cl. 136/256; 528/8; 528/425

(57) ABSTRACT

The invention provides a photovoltaic cell comprising a photovoltaic layer comprising a conjugated polymer comprising monomer units of the formula (I) wherein X, A, B, a and b are as defined herein. The invention further provides the use of a conjugated polymer comprising monomer units of formula (I) as a photovoltaic material in a photovoltaic cell.

### FIELD OF THE INVENTION

The present invention relates to polymers that contain a dipole for use in photovoltaic cells and can assist in separating the exciton formed on excitation by light into charges.

### DESCRIPTION OF THE PRIOR ART

Polymer-based photovoltaic cells have been intensively investigated. In such cells three key processes need to occur: light absorption, charge separation of the exciton, and transport of the separated charges to the electrodes. Light absorption is reliant on the optical density of the polymer. In general charge separation is achieved by blending an electron acceptor with the polymer film.

Research has therefore considered whether charge separation can be achieved intramolecularly for simpler manufacturing. Conjugated polymers for use in photovoltaic cells have therefore been prepared which contain both electron donating and withdrawing groups, allowing for the possibility of intramolecular charge separation. However, these polymers contain the electron donating and withdrawing groups on different monomers of the copolymer backbone. For example, in a structure -A-B-A-B-A-B- the electron donating groups may be present on the -A- groups, and the electron withdrawing groups may be present on the -B- groups. While this arrangement does allow for a localised dipole and in principle a charge separated state, there can be a limit to the distance by which charge can be separated, and this limit depends on the size and separation of the A and B groups in the structure above.

There is therefore a need for new polymer-based photovoltaic cells to be prepared which achieve more efficient charge separation.

### SUMMARY OF THE INVENTION

The invention provides a photovoltaic cell comprising a photovoltaic layer comprising a conjugated polymer comprising monomer units of the formula (I):

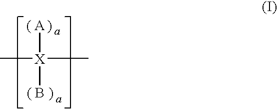

wherein:
X is selected from C₆₋₁₄ arylene, C₆₋₁₄ arylene-vinylene and C₆₋₁₄ arylene-acetylene units;
each A represents a group of formula -(L)₁-EWG wherein EWG is an electron-withdrawing group;
a is 1, 2 or 3;
1 is zero or an integer of from 1 to 10;
L is a spacer group selected from C₆₋₁₄ arylene, (C₆₋₁₄ arylene)-vinylene, (C₆₋₁₄ arylene)-acetylene, 5- to 10-membered heteroarylene, (5- to 10-membered heteroarylene)-vinylene, and (5- to 10-membered heteroarylene)-acetylene groups, wherein the arylene and heteroarylene moieties are unsubstituted or substituted by one or more groups selected from C₁₋₁₀ alkyl, C₁₋₁₀ alkoxy and EWG groups defined above;
each B represents a group of formula -(L′)_{1′}-EDG wherein EDG is an electron-donating group;
b is 1, 2 or 3;
1′ is zero or an integer of from 1 to 10;
L′ is a spacer group selected from C₆₋₁₄ arylene, (C₆₋₁₄ arylene)-vinylene, (C₆₋₁₄ arylene)-acetylene, 5- to 10-membered heteroarylene, (5- to 10-membered heteroarylene)-vinylene, and (5- to 10-membered heteroarylene)-acetylene groups, wherein the arylene and heteroarylene moieties are unsubstituted or substituted by one or more groups selected from C₁₋₁₀ alkyl, C₁₋₁₀ alkoxy and EDG groups defined above;
when 1 is greater than zero, EWG is attached to an arylene, heteroarylene, vinylene or acetylene moiety of L;
when 1′ is greater than zero, EDG is attached to an arylene or heteroarylene moiety of L′; and
1 and 1′ are not both zero.

The invention also provides the use of a conjugated polymer comprising monomer units of formula (I), as defined above, as a photovoltaic material. Photovoltaic materials are materials that participate in the conversion of absorbed light to electricity. For example, photovoltaic materials are preferably materials which can absorb light to form an exciton and through which charge can migrate.

The polymers used in the invention assist in charge separation by employing groups attached to the polymer backbone that will stabilize both the holes and the electrons that are formed when the exciton is separated. This is achieved by having electron-withdrawing and electron-donating groups across the substituents of the backbone. Such an arrangement will give rise to a dipole and it should be noted that the factors that control dipole strength are well known to those skilled in the art of producing second-order non-linear optic materials (see, for example, H Meier, Angew. Chem. Int. Ed., 2005, 44, 2482).

### BRIEF DESCRIPTION OF THE FIGURE

FIG. 1 shows the UV-visible spectra of polymers used in the invention.

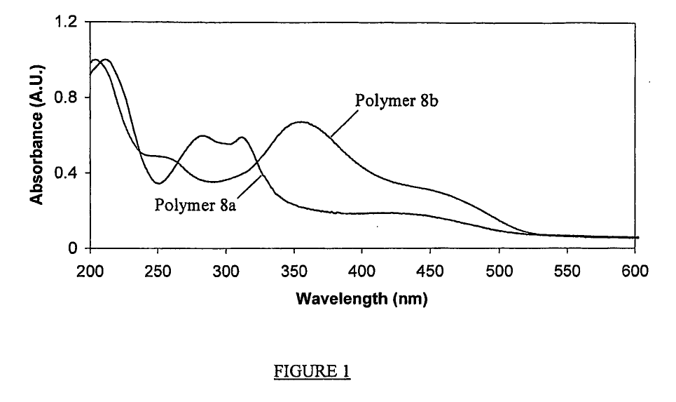

### DETAILED DESCRIPTION OF THE INVENTION

As used herein the term C₁₋₁₀ alkyl is a linear or branched alkyl group or moiety containing from 1 to 10 carbon atoms such as a C₁₋₄ or C₁₋₆ or C₁₋₈ alkyl group or moiety. Examples of C₁₋₄ alkyl groups and moieties include methyl, ethyl, n-propyl, i-propyl, n-butyl, i-butyl and t-butyl. For the avoidance of doubt, where two alkyl moieties are present in a group, the alkyl moieties may be the same or different.

As used herein, a C₂₋₆ alkenyl group or moiety is a linear or branched alkenyl group or moiety containing from 2 to 6 carbon atoms respectively such as a C₂₋₄ alkenyl group or moiety. For the avoidance of doubt, where two or more alkenyl moieties are present in a group, the alkenyl moieties may be the same or different.

As used herein, a halogen is typically chlorine, fluorine, bromine or iodine. It is preferably chlorine, fluorine or bromine, more preferably fluorine.

As used herein the term amino represents a group of formula —NH₂. The term C₁₋₁₀ alkylamino represents a group of formula —NHR′ wherein R′ is a C₁₋₁₀ alkyl group, preferably a C₁₋₈ alkyl group, as defined previously. The term di(C₁₋₁₀)alkylamino represents a group of formula —NR′R″ wherein R′ and R″ are the same or different and represent C₁₋₁₀ alkyl groups, preferably C₁₋₈ alkyl groups, as defined previously. As used herein the term amido represents a group of formula —C(O)NR′R″ wherein R′ and R′ are the same or different and are selected from hydrogen and C₁₋₁₀ alkyl groups, more preferably from hydrogen and C₁₋₈ alkyl groups as defined previously.

As used herein the term aryl refers to C₆₋₁₄ aryl groups which may be mono- or polycyclic, such as phenyl, naphthyl and fluorenyl. An aryl group may be unsubstituted or substituted at any position. Unless otherwise stated, it carries 0, 1, 2 or 3 substituents in addition to any group EWG or EDG that is present. Preferred substituents on an aryl group include C₁₋₁₀ alkyl groups, because such groups improve the solubility in polar aprotic solvents, such as toluene, xylene, chlorobenzene, tetrahydrofuran and chloroform. If the aryl group is part of the group B, then the substituents are preferably electron-donating groups, such as the groups EDG as exemplified herein. However, if the aryl group is part of the group A, then it is preferred that the substituents are not strongly electron-donating groups. For example, if the aryl group is part of the group A, then the substituents may be groups EWG as exemplified herein or alkyl.

As used herein, a heteroaryl group is typically a 5- to 14-membered aromatic ring, such as a 5- to 10-membered ring, more preferably a 5- or 6-membered ring, containing at least one heteroatom, for example 1, 2 or 3 heteroatoms, selected from O, S and N. Examples include pyridyl, pyrazinyl, pyrimidinyl, pyridazinyl, furanyl, thienyl, pyrrolyl, oxadiazolyl, thiadiazolyl, thiazolyl, imidazolyl, oxazolyl, benzofuranyl, indolyl, indazolyl, carbazolyl, purinyl, cinnolinyl, quinoxalinyl, naphthyridinyl, benzimidazolyl, benzoxazolyl, quinolinyl, quinazolinyl and isoquinolinyl.

Preferred heteroaryl groups include thiophenyl, pyrrolyl, pyridyl, furanyl, oxadiazolyl and carbazolyl.

When the heteroaryl group is a monocyclic heteroaryl group, preferred groups include thiophenyl, pyrrolyl, pyridyl, furanyl and oxadiazolyl.

As used herein, references to a heteroaryl group include fused ring systems in which a heteroaryl group is fused to an aryl group. When the heteroaryl group is such a fused heteroaryl group, preferred examples are fused ring systems wherein a 5- to 6-membered heteroaryl group is fused to one or two phenyl groups. Examples of such fused ring systems are benzofuranyl, benzopyranyl, cinnolinyl, carbazolyl, benzotriazolyl, phenanthridinyl, indolyl, indazolyl, benzimidazolyl, benzoxazolyl, quinolinyl, quinazolinyl and isoquinolinyl moieties.

A heteroaryl group may be unsubstituted or substituted at any position. Unless otherwise stated, it carries 0, 1, 2 or 3 substituents. Preferred substituents on a heteroaryl group include those listed above in relation to aryl groups.

As used herein, arylene and heteroarylene groups respectively represent aryl and heteroaryl groups which are capable of bonding to at least two other groups, i.e. which are at least divalent. The aryl and heteroaryl groups are as defined above. As used herein, an alkoxy group is typically a said alkyl group attached to an oxygen atom. Similarly, alkenyloxy groups and aryloxy groups are typically a said alkenyl group or aryl group respectively attached to an oxygen atom. An alkylthio group is typically a said alkyl group attached to a thio group. Similarly, alkenylthio groups and arylthio groups are typically a said alkenyl group or aryl group respectively attached to a thio group. A haloalkyl or haloalkoxy group is typically a said alkyl or alkoxy group substituted by one or more said halogen atoms. Typically, each carbon atom of said group is substituted by one or more halogen atoms, with the maximum number of halogen atoms being the number required to bring the total valency of the carbon atom to four. Haloalkyl and haloalkoxy groups include perhaloalkyl and perhaloalkoxy groups such as —CX₃, —CX₂CX₃ and —OCX₃ wherein X is a said halogen atom, for example chlorine or fluorine, as well as longer alkyl and/or alkoxy chains such as C₂₋₆ chains substituted by one or more halogen atoms.

Haloaryl groups are, by analogy, typically a said aryl group substituted by one or more said halogen atoms. Typically, it is substituted by 1, 2 or 3 said halogen atoms.

As used herein, a sulfoxide group is typically a group of the formula —SOR wherein R is a said alkyl or aryl group. A sulfone group is typically a group of the formula —SO₂R wherein R is a said alkyl or aryl group.

Turning now to the different portions of the polymers used in the invention and discussing each in turn:

### Polymer Backbone (X):

Units of the polymer backbone, designated X in formula (I), are selected from C₆₋₁₄ arylene, C₆₋₁₄ arylene-vinylene and C₆₋₁₄ arylene-acetylene units. Preferred C₆₋₁₄ arylene groups include phenylene and fluorenylene, with phenylene being preferred. In addition to the groups A and B that are present as substituents, these arylene groups are further unsubstituted or are further substituted by one, two or three groups selected from C₁₋₁₀ alkyl and C₁₋₁₀ alkoxy. Preferred further substituents are C₁₋₈ alkyl groups which are themselves unsubstituted.

Preferably the polymer backbone consists only of arylene, vinylene and acetylene units. In particular, it is preferred that there are no heteroatoms such as nitrogen, oxygen, sulphur or silicon present as atoms in the backbone itself.

In one embodiment the polymer backbone consists of groups selected from the arylene, arylene-vinylene and/or arylene-acetylene units defined above, substituted by the groups A and B. In other words, there are no other monomer units present in the polymer backbone. In another embodiment, the polymer backbone also includes other monomers. In other words, the polymer is a copolymer of arylene, arylene-vinylene and/or arylene-acetylene units defined above which are substituted by the groups A and B, along with another monomer or monomers.

Examples of the other monomer or monomers include arylene, arylene-vinylene, arylene-acetylene, heteroarylene, heteroarylene-vinylene and heteroarylene-acetylene units. The arylene and heteroarylene moieties in said other monomer or monomers may be unsubstituted or substituted by any of the functional groups described above. The substituents may, for example, be chosen in such a way as to make the spectrum of the copolymer match more fully the solar spectrum.

The polymer backbone units bear groups A and B. Integers a and b define, respectively, the number of A and B units. Preferably a is 1 or 2, more preferably 1. Preferably b is 1 or 2, more preferably 1.

### Electron Donating Groups (EDGs):

The electron donating groups are in conjugation with the polymer backbone and are capable of stabilising a hole once an exciton has been generated separated. Preferred electron donating groups include C₁₋₁₀ alkyl, C₁₋₁₀ alkoxy, amino, C₁₋₁₀ alkylamino and di(C₁₋₁₀ alkyl)amino. In particular, C₁₋₁₀ alkylamino and di(C₁₋₁₀ alkyl)amino are preferred. Preferred alkoxy groups include C₁₋₈ alkoxy groups which are unsubstituted or substituted by one, two or three groups selected from C₁₋₄ alkyl groups and C₁₋₄ alkoxy groups. More preferred alkoxy groups include C₁₋₈ alkoxy groups such as C₁₋₆ alkoxy groups, which are unsubstituted or substituted by one or two C₁₋₄ alkyl groups. A more preferred alkoxy group is 2-ethylhexyloxy.

### Electron Withdrawing Groups (EWGs):

The electron-withdrawing groups are in conjugation with the polymer backbone and are capable of stabilising an electron once an exciton has been generated and separated.

Suitable electron withdrawing groups include nitro, cyano, acid amide, ketone, phosphinoyl, phosphonate, ester, sulfone, sulfoxide, halo(C₁₋₆ alkyl), and halo(C₆₋₁₄ aryl) groups. In particular, nitro, cyano, ketone, sulfone, sulfoxide, halo(C₁₋₆ alkyl) and halo(C₆₋₁₄ aryl) are preferred. Preferred acid amide groups include tertiary acid amide groups. Preferred ketone groups include diarylketones. Preferred ester groups include groups of the formula —CO₂R where R is a C₁₋₁₀ alkyl group such as a methyl or ethyl group, or a C₆₋₁₄ aryl group. Preferred sulfone groups include groups of the formula —SO₂R where R is a C₁₋₁₀ alkyl group such as a methyl or ethyl group, or a C₆₋₁₄ aryl group. More preferred sulfone groups are —SO₂Me groups. Aryl sulfones are especially preferred. Preferred sulfoxide groups include groups of the formula —SOR where R is a C₁₋₁₀ alkyl group such as a methyl or ethyl group, or a C₆₋₁₄ aryl group. More preferred sulfoxide groups are —SOMe groups. Arylsulfoxides are especially preferred. Preferred haloalkyl groups include C₁₋₆ alkyl groups substituted by one or more halogen atoms, for example trifluoromethyl. Haloalkyl groups may be perhalogenated, e.g. perfluorinated. Preferred haloaryl groups include C₆₋₁₄ aryl groups which may be mono- or polycyclic, such as phenyl, naphthyl and fluorenyl. Haloaryl groups may be perhalogenated, e.g. perfluorinated. Especially preferred electron withdrawing groups are cyano, nitro and sulfone groups.

### Spacer Groups (L and L′):

The spacer groups L and L′ are selected from C₆₋₁₄ arylene, (C₆₋₁₄ arylene)-vinylene, (C₆₋₁₄ arylene)-acetylene, 5- to 10-membered heteroarylene, (5- to 10-membered heteroarylene)-vinylene and (5- to 10-membered heteroarylene)-acetylene groups, wherein the arylene and heteroarylene moieties are unsubstituted or substituted by one or more groups selected from C₁₋₁₀ alkyl and C₁₋₁₀ alkoxy. In the case of L, the arylene and heteroarylene moieties can be substituted by further EWG groups defined above. In the case of L′, the arylene and heteroarylene moieties can be substituted by further EDG groups defined above.

Preferred L and L′ groups include C₆₋₁₄ arylene and (C₆₋₁₄ arylene)vinylene groups, wherein the C₆₋₁₄ arylene groups and the C₆₋₁₄ arylene moieties of the (C₆₋₁₄ arylene)-vinylene groups are unsubstituted or substituted by one or more groups, preferably one or two groups, selected from C₁₋₁₀ alkyl and C₁₋₁₀ alkoxy. Preferred C₆₋₁₄ arylene groups and moieties include phenylene, naphthylene and fluorenylene, in particular phenylene and fluorenylene.

Preferred 5- to 10-membered heteroarylene groups and moieties within the definition of L include heteroarylene with a relatively high electron affinity, such as pyridine. Preferred 5- to 10-membered heteroarylene groups and moieties within the definition of L′ include heteroarylene with a relatively low electron affinity, such as thiophene.

Preferred substituents on the arylene and heteroarylene groups include C₁₋₁₀ alkyl groups, for example C₁₋₄ alkyl groups such as methyl, ethyl, propyl and butyl groups. Additionally, if the arylene group or heteroarylene group is part of the group B, then the substituents are preferably electron-donating groups, such as the groups EDG as exemplified herein. However, if the arylene group or heteroarylene group is part of the group A, then it is preferred that the substituents are not strongly electron-donating groups. For example, if the arylene group or heteroarylene group is part of the group A, then the substituents may be groups EWG as exemplified herein or alkyl, preferably C₁₋₄ alkyl groups. For example, a particularly preferred L group is a fluorenyl group which is disubstituted by n-propyl groups (see, for example, Scheme 1 below).

The 1 and 1′ subscripts define the number of spacer groups present between the backbone and the EWG and EDG groups respectively. Preferably 1 is zero or an integer of from 1 to 5, more preferably zero, 1, 2, 3 or 4, even more preferably zero, 1, 2 or 3. In most preferred embodiments, 1 is 1 or 2. Preferably 1′ is zero or an integer of from 1 to 5, more preferably zero, 1, 2 or 3, even more preferably zero, 1 or 2. In most preferred embodiments 1′ is zero.

Where 1 and/or 1′ is an integer of 2 or more, then 2 or more spacer groups are present between the polymer backbone and the group EWG or EDG. In this embodiment, the spacer groups are the same or different. For example, when 1 is 2, a fluorenylene group and a phenylene group could be present between the polymer backbone and EWG. In another embodiment, two fluorenylene groups could be present between the polymer backbone and EWG. The number of spacer groups between EDG and EWG will govern the strength of the dipole.

In a preferred embodiment of the invention, there is provided a photovoltaic cell as defined above wherein the conjugated polymer comprises monomer units of one or more of formulae (IIA), (IIB) and (IIC):

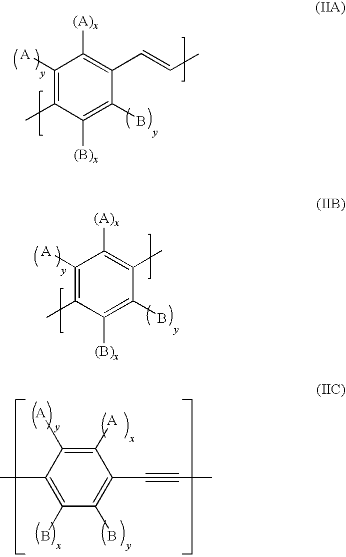

wherein A, B, L, L′, 1, 1′, EWG and EDG are as defined above, each x is zero or one, and each y is zero or one provided that at least one A group and at least one B group are present. Preferred values of A, B, L, L′, 1, 1′, EWG and EDG are as defined earlier. It is preferred that either x is 1 and y is zero, or x is zero and y is 1.

For the avoidance of doubt, it should be noted that the conjugated polymer may include head-to-head, head-to-tail and tail-to-tail couplings of the monomer units.

It is further preferred that the conjugated polymer comprises monomer units of one or more of formulae (IIIA), (IIIB) and (IIIC):

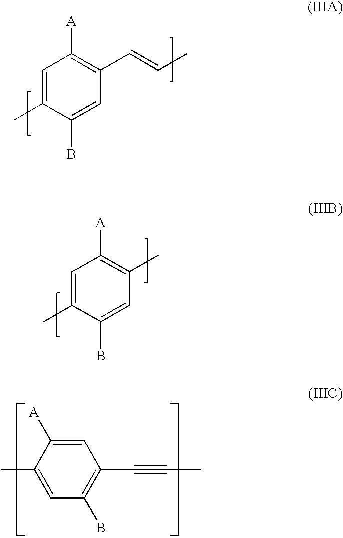

wherein A, B, L, L′, 1, 1′, EWG and EDG are as defined above. Again, preferred values of A, B, L, L′, 1, 1′, EWG and EDG are as defined above.

### Processes:

The polymers used in the present invention may be prepared by analogy with known preparation processes. The strategies for forming poly[(hetero)arylenevinylene], poly[(hetero)aryleneacetylene] and poly[(hetero)arylene] homo- and copolymers are well known and are reviewed in detail by J. L. Segura, Acta. Polym., 1998, 49, 319. Simple conjugated polymers are inherently insoluble and hence unprocessible. The main strategy used to overcome this is to attach side chains to the polymer backbone. For example, alkyl or alkoxy side chains of the appropriate length such can impart solubility in polar aprotic solvents such as toluene, chlorobenzene, tetrahydrofuran and chloroform.

The main route to poly[(hetero)arylenevinylene]s is via the Gilch route or variants thereof. Poly[(hetero)arylenevinylene]s can either be prepared so they are soluble in their conjugated form, by the attachment of solubilising groups, as are preferably used in the present invention, or via a soluble precursor polymer that can be processed and converted in the solid state to the conjugated polymer. The advantage of the latter route is that the no solubilising side-chain may be needed.

Poly[(hetero)arylenevinylene]s can also be formed by Wittig chemistry and palladium catalysed Heck reactions. These latter strategies allow for the simple formation of homo- and copolymers.

Poly[(hetero)aryleneacetylene]s can be formed via Sonogashira type chemistry. For example a homopolymer can be formed from a monomer that contains a (hetero)arylene unit with a halogen moiety and an acetylene moiety. Alternatively a monomer that has two acetylene units can be polymerized with one containing two halide moieties. With the latter method if the (hetero)arylene unit is the same in both cases a homopolymer is formed, but if they are different a copolymer is formed.

Poly[hetero(arylene)]s are generally made from palladium catalysed Suzuki or Stille couplings with the synthesis of homo- and copolymers following the same strategies as used for the poly[(hetero)aryleneacetylene]s.

The polymers used in the present invention may be prepared using each of the general methods described above.

An exemplary process, which is used in the preparation of the polymers prepared in the Examples, is shown in Scheme 1 below:

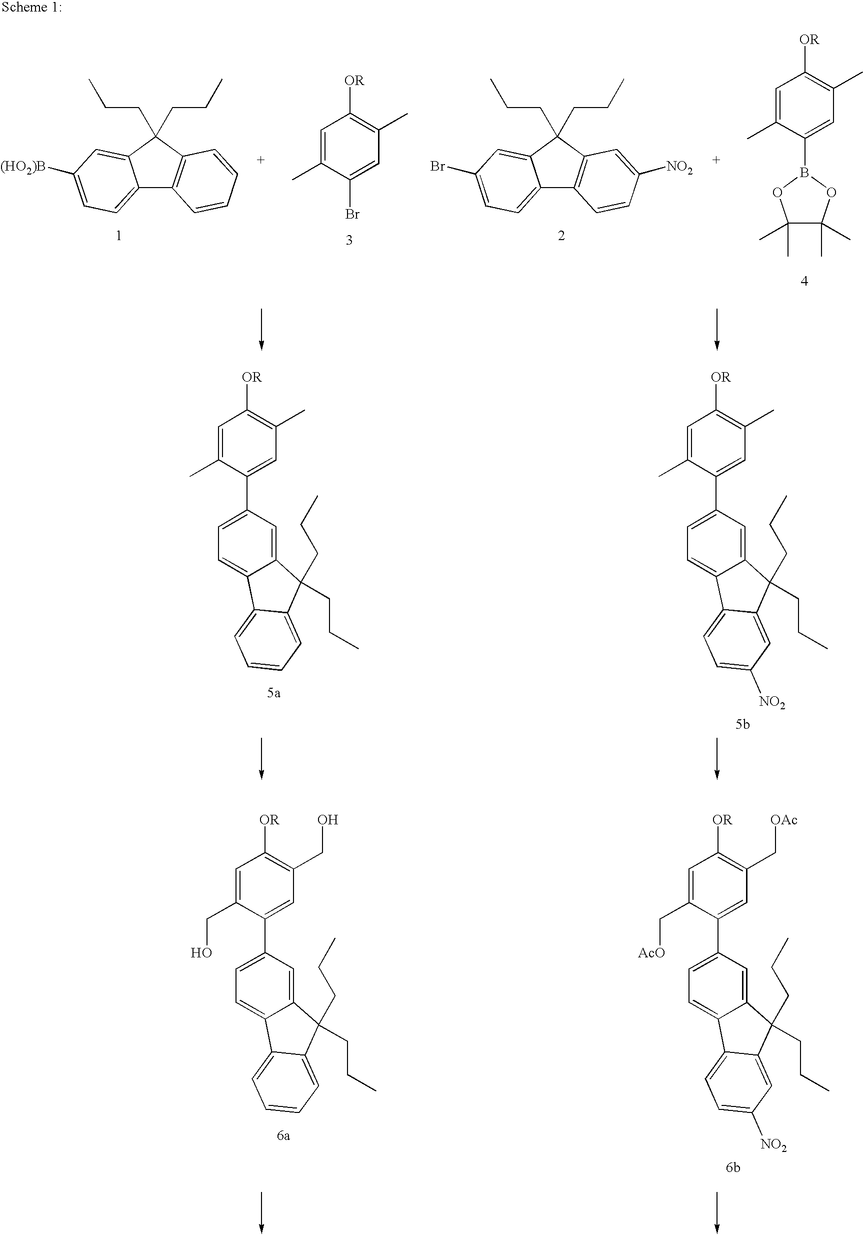

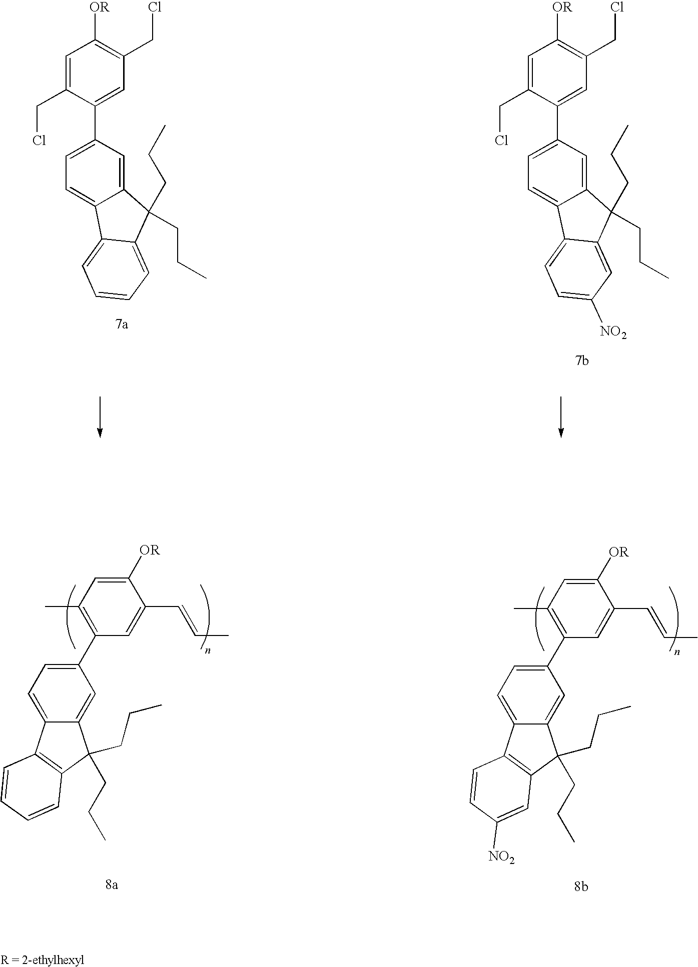

### Devices:

The structures of organic photovoltaic cells are well known and general descriptions of the device types and method of working can be found in H. Spangaard and F. C. Krebs, Solar Energy Mat. and Solar cells, 2004, 83, 125 and H. Hoppe et al., J. Mat. Res., 2004, 1924. A simple photovoltaic cell according to the present invention comprises a photovoltaic organic layer comprising a conjugated polymer comprising monomer units of formula (I) sandwiched between an anode and cathode, one of which is transparent to allow the ingress of light. The photovoltaic layer is typically 20 nm to 300 nm thick and preferably 50 nm to 150 nm thick. The photovoltaic layer can consist entirely of the polymer comprising monomer units of formula (I), or the polymer can be blended with other polymers or small molecules to aid light absorption, charge separation and/or charge transport. For example, to aid charge separation an electron acceptor such as soluble form of C₆₀ may be added. To aid charge transport electron transporting materials such as 2,9-dimethyl-4,7-diphenyl-1,10-phenanthroline (BCP), 1,3,5-tris(2-N-phenylbenzimidazolyl)benzene (TPBI) and 2-biphenyl-5(4′-t-butylphenyl)oxadiazole (PBD) and hole transporting materials such as TPD (N,N′-diphenyl-N,N′-bis(3-methylphenyl)[1,1′-biphenyl]-4,4′-diamine), NPD (4,4′-bis[N-naphthyl)-N-phenyl-amino]biphenyl) and MTDATA may be added. Where a blend of materials is used these can be known as bulk heterojunction devices.

Alternatively the device may have one or more layers with at least one layer comprising a polymer comprising monomer units of formula (I). These multilayer devices are often termed heterojunction devices. For example, a bilayer heterojunction device could have the structure Cathode/Electron acceptor/Electron donor/Anode. The layers may be either organic materials or inorganic materials such as titanium dioxide or tin oxide. The number of layers and components within the layers are optimized to ensure efficient light-absorption, charge separation and transport.

The choice of the electrodes of the photovoltaic device is dependent on the structure type. Typically when a metal oxide is used as the electron acceptor the metal oxide is deposited onto ITO and the second electrode is a high work function metal such as gold. If the device contains only organic materials then ITO is often used as the transparent electrode in combination with a low work function metal as the second electrode. Suitable high work function materials may be selected from the group comprising indium-tin oxide (ITO), tin oxide, aluminum or indium doped zinc oxide, magnesium-indium oxide, cadmium tin-oxide, gold, silver, nickel, palladium and platinum. ITO is a preferred example as the transparent electrode for use in the claimed photovoltaic devices. Conducting polymers such as PANI (polyaniline) or PEDOT can also be used. The electrode material is deposited by sputtering or vapour deposition as appropriate. Low work function materials may be selected from the group including Li, Na, K, Rb, Be, Mg, Ca, Sr, Ba, Yb, Sm, and Al. The low work function electrode may comprise an alloy of such metals or an alloy of such metals in combination with other metals, for example the alloys MgAg and LiAl. The electrode may thus comprise multiple layers, for example Ca/Al, Ba/Al, or LiF/Al. The device may further comprise a layer of dielectric material between the cathode and the emitting layer, such as is disclosed in WO 97/42666. For example, an alkali or alkaline earth metal fluoride may be used as a dielectric layer between the cathode and the organic semiconductor.

The photovoltaic device may include further organic layers between the anode and cathode to improve charge extraction and device efficiency. In particular a layer of conductive or hole-transporting material may be situated over the anode. This layer serves to increase charge conduction through the device. The preferred anode coating in polymer devices is a conductive organic polymer such as polystyrene sulfonic acid doped polyethylene dioxythiophene (PEDOT:PSS) as disclosed in WO98/05187. Other hole transporting materials such as doped polyaniline, TPD, NPD and MTDATA may also be used.

A layer of electron transporting material may be next to the cathode as this can improve device efficiency. Suitable materials for electron transporting layers include BCP, TPBI and PBD.

The substrate of the photovoltaic device should provide mechanical stability to the device and act as a barrier to seal the device from the environment. Where it is desired that light enter the device through the substrate, the substrate should be transparent or semi-transparent. Glass is widely used as a substrate due to its excellent barrier properties and transparency. Other suitable substrates include ceramics, and plastics such as acrylic resins, polycarbonate resins, polyester resins, polyethylene terephthalate resins and cyclic olefin resins. Plastic substrates may require a barrier coating to ensure that they remain impermeable. The substrate may comprise a composite material such as the glass and plastic composite.

To provide environmental protection the device may be encapsulated. Encapsulation may take the form of a glass sheet which is glass bonded to the substrate with a low temperature frit material. To avoid the necessity of using a glass sheet to encapsulate the device a layer of passivating material may be deposited over the device. Suitable barrier layers comprise a layered structure of alternating polymer and ceramic films and may be deposited by PECVD. Alternatively the device may be encapsulated by enclosure in a metal can.

Preferred device structures for the photovoltaic cells of the invention include the structure ITO/PEDOT:PSS/Polymer/Al or the polymer blended with another material in a single or multilayer device.

Photovoltaic devices of the invention may be prepared by any suitable method known to those skilled in the art. Where the polymers of the invention are soluble they may be advantageously deposited by solution processing techniques. Solution processing techniques include selective methods of deposition such as screen printing and ink-jet printing and non-selective methods such as spin coating and doctor blade coating. If a precursor polymer is used then after solution processing it is thermally converted under vacuum or an inert atmosphere to the conjugated polymer. Other layers may be deposited by evaporation or solution processing providing that any subsequent solution processing step does not substantially remove the already deposited layers.

The invention will be described in the Examples which follow.

### EXAMPLES

### Measurements and Materials

NMR spectra were recorded on a Bruker 400 M Hz spectrometer; J values are reported in Hz. IR spectra were recorded on a Spectrum 1000 IR spectrometer and analysed as either a thin film or a KBr disc. UV-visible spectra were recorded on a Perkin-Elmer UV lambda 15 spectrometer as either a thin film or as a solution in spectroscopic grade dichloromethane. Spin coated samples were prepared by drop casting the substrate with a filtered polymer solution and spinning was carried out at 2000 r.p.m. for 60 seconds on a Dynapert PRS 14E spinner for photoresists, the solvent was allowed to evaporate under ambient conditions. Mass spectra were recorded either on a Hewlett Packard 1050 Atmospheric Pressure Chemical Ionisation mass spectrometer (APCI) or VG platform spectrometer. Electronic ionisation was recorded on a Bio-Q spectrometer. Microanalysis was carried out by Mrs. A. Douglas, Inorganic Chemistry Research Laboratory, University of Oxford. Melting points were determined on a Gallenkamp melting point apparatus and are uncorrected. Gel permeation chromatography was carried out with a Polymer Laboratories PL gel 20 μm Mixed A columns (600 mm length and 7 mm diameter) calibrated with polystyrene standards (580-11.2×10⁶) in tetrahydrofuran with toluene as a flow marker. The UV detector was set at 245 nm and solvent was pumped at a flow rate of 1 ml/min.

### Comparative Example

### Preparation of Poly{2-[(9,9-dipropyl-9H-fluorene)-5-(2′-ethyl-hexyloxy)-1,4-phenylenevinylene]} (8a)

### (a) 9,9-di(n-propyl)-2-fluorene Boronic Acid (1)

50% Aqueous sodium hydroxide (500 mL) was added to a solution of 2-bromofluorene (52.8 g, 215 mmol) and tetrabutylammonium bromide (3.47 g, 10.8 mmol) in toluene (500 mL), and heated to 50° C. After 90 minutes 1-bromopropane (60 mL, 650 mmol) was added, and the solution stirred at 50° C. for 16 hours. The organic layer was separated, washed with water (2×500 mL), brine (500 mL), dried over magnesium sulfate, and the solvent removed. Recrystallisation from a dichloromethane/methanol mixture gave 9,9-dipropyl-2-bromofluorene (51.5 g, 73%).

Tert-butyl lithium (87 mL, 1 M solution in pentane, 150 mmol) was added to a solution of 9,9-dipropyl-2-bromofluorene prepared as described above (44.4 g, 135 mmol) in THF (600 mL) which had been cooled in a dry ice/acetone bath. After 1 hour trimethylborate (77 mL, 680 mmol) was added, and the solution stirred for 16 hours gradually warming to room temperature. Aqueous hydrochloric acid (3 M, 80 mL) was added, and the solution stirred for 2 hours. The layers were separated, and the aqueous layer was extracted with diethyl ether (3×20 mL). The combined organic extracts were washed with brine (500 mL), dried over magnesium sulfate and the solvent was removed. Purification by silica plug (using light petroleum then diethyl ether as the eluent) gave 1 (24.3 g, 61%).

### (b) 2-[4-(2′-Ethyl-hexyloxy)-2,5-dimethyl-phenyl]-9,9-dipropyl-9H-fluorene (5a)

A mixture of 1-bromo-4-(2′-ethylhexyloxy)-2,5-dimethylbenzene 3 (2.6 g, 4.5 mmol), 9,9-di(n-propyl)-2-fluorene boronic acid 1 (2.0 g, 6.8 mmol), aqueous sodium bicarbonate (2M, 25 mL) in toluene (25 mL) was deoxygenated with nitrogen for 15 minutes. Compound 3 can be obtained as described in F. H, Boardman et al, Macromolecules, 1999, 32, 111. To this tetrakis(triphenylphosphine) palladium (0) (0.21 g, 0.18 mmol) was added and reaction was heated at reflux for 5 hours under a nitrogen atmosphere. After cooling, the aqueous layer was separated and organic layer was washed with water (50 mL), aqueous hydrochloric acid (2×30 mL), brine (50 mL), and dried over anhydrous magnesium sulphate, filtered, and then the solvent was removed. The residue was purified by chromatography over silica using light petroleum:dichloromethane (6:1) as eluent to give 5a (1.76 g, 54%), bp 220° C., 0.1 mmHg. (Found: C, 87.08; H, 9.60. C₃₅H₄₆O requires C, 87.08; H, 9.60%); δ_{H} (CDCl₃, 400 MHz) 0.65-0.78 (10H, m), 0.95-1.04 (6H, m), 1.38-1.64 (8H, m), 1.78-1.86 (1H, m), 1.98-2.06 (4H, m), 2.28 (3H, s), 2.32 (3H, s), 3.91 (2H, d, J 5.5), 6.79 (1H, s), 7.14 (1H, s), 7.34 (5H, m) and 7.74 (2H, d, J 7.5).

### (c) 2-[2,5-Bis-hydroxymethyl-4-(2′-ethyl-hexyloxy)-phenyl]-9,9-dipropyl-9H-fluorene (6a)

A suspension of 5a (5.7 g, 11.8 mmol), N-bromosuccinimide (3.1 g, 26.0 mmol), carbon tetrachloride (50 mL) was deoxygenated with nitrogen for 10 minutes. 2,2′-Azo-bis(iso-butyronitrile) (0.7 g, 4.1 mmol) was added and reaction heated at reflux for 2 hours. After cooling, the reaction mixture was passed through silica plug using dichloromethane as eluent. The solvent was removed and sodium acetate (9.7 g, 118.0 mmol) and glacial acetic acid (100 mL) were added. The reaction mixture was heated at reflux for 5 hours. After cooling water (100 mL) was added and the aqueous layer was extracted with ether (3×100 mL). The ether extracts were combined and washed with sodium hydroxide solution (5% w/v, 100 mL), saturated solution of sodium bicarbonate (2×25 mL) and water (100 mL). The organic layer was dried over anhydrous magnesium sulphate, filtered and the solvent removed. The residue was dissolved in anhydrous tetrahydrofuran (125 mL), stirred at 0° C. under nitrogen atmosphere and then lithium aluminium hydride (0.9 g, 24.0 mmol) was added in portions. After 10 minutes, the reaction mixture was allowed to stir at room temperature for 2 hours. The reaction was carefully quenched with hydrochloric acid (3M, 10 mL) and then water (100 mL) was added. The aqueous was extracted with ether (3×75 mL), washed with water (2×100 mL), brine (100 mL) and dried over anhydrous magnesium sulphate filtered, and then the solvent was removed. The residue was purified by column chromatography over silica first using dichloromethane as eluent then using dichloromethane:methanol (50:1) as eluent to give 6a (1.97 g, 32%), mp 97.0-98.0° C. (Found: C, 81.45; H, 9.01. C₃₅H₄₆O₃ requires C, 81.67; H, 9.01%); δ_{H} (CDCl₃, 400 MHz) 0.68-0.81 (10H, m), 0.96-1.04 (6H, m), 1.48-1.63 (8H, m), 1.84-1.92 (1H, m), 1.98-2.03 (4H, m), 4.08 (2H, d, J 5.5), 4.72 (2H, s), 4.81 (2H, s), 7.24 (1H, s), 7.32 (6H, m), 7.76 (2H, dd, J 7.9, J 2.1).

### (d) 2-[2,5-Bis-chloromethyl-4-(2′-ethyl-hexyloxy)-phenyl]-9,9-dipropyl-9H-fluorene (7a)

Thionylchloride was added to a solution of 6a (1.7 g, 3.3 mmol) in anhydrous dichloromethane at 0° C. under nitrogen. After addition, the reaction was allowed to warm up to room temperature and stirred for a further 3 hours. The solvent and excess thionylchloride were removed and the residue was purified flash chromatography over silica gel using light petroleum:dichloromethane (1:1) as eluent to give 7a (1.8 g, 96%), mp 58.0-59.0° C.; δ_{H} (CDCl₃, 400 MHz) 0.75-0.88 (10H, m), 0.98-1.10 (6H, m), 1.46-1.78 (8H, m), 1.92-1.99 (1H, m), 2.04-2.14 (4H, m), 4.12 (2H, d, J 4.8), 4.63 (2H, s), 4.81 (2H, s), 7.02 (1H, s), 7.45 (5H, m), 7.62 (1H, s), 7.84 (2H, dd, J 8, J 2.1); Exact mass 550.2769. C₃₅H₄₄Cl₂O requires 550.2769.

### (e) Poly{2-[(9,9-dipropyl-9H-fluorene)-5-(2′-ethyl-hexyloxy)-1,4-phenylenevinylene]} (8a)

A solution of potassium tert-butoxide (0.57 g, 5.09 mmol) in dry tetrahydrofuran (25.5 mL) was added to a stirred solution of 8a (0.56 g, 1.02 mmol) in anhydrous tetrahydrofuran (5.1 mL) at room temperature under nitrogen in the dark and then the reaction mixture was stirred for 3 hours. The solution was filtered through a cotton wool plug and precipitated in ice-cold methanol (100 mL). The mixture was centrifuged (4500 rpm, 5 minutes) and the supernatant was decanted, The yellow residue was re-dissolved in tetrahydrofuran (65 mL) and reprecipitated in ice-cold methanol (120 mL). The precipitate obtained was separated by centrifugation (4500 rpm, 5 minutes) and the supernatant was removed. The residue was dried under vacuum for 18 hours to give 8a (180 mg, 37%). νₘₐₓ (film, KBr disc)/cm⁻¹ 951 (C═C—H trans); λₘₐₓ (film)/nm 441, 311, 281 and 212; M̅_{w}=4.3×10⁶, M̅ₙ=1.9×10⁶ and PD=2.3.

### Example 1

### Preparation of Poly{2-[2-(7-nitro-9,9-dipropyl-9H-fluorene)]-5-(2′-ethyl-hexyloxy)-1,4-phenylenevinylene} (8b)

### (a) 2-[4-(2′-ethyl-hexyloxy)-2,5-dimethyl-phenyl]-4,4,5,5-tetramethyl-[1,3,2]dioxaborolane (4)

Tert-butyllithium (1.7 M in pentane, 100 mL, 0.17 mol) was added to a solution of 1-bromo-4-(2′-ethylhexyloxy)-2,5-dimethylbenzene 3 (29.6 g, 94 mmol) in anhydrous tetrahydrofuran (250 mL) at −78° C. under argon. The reaction mixture was stirred for 1 hour at −78° C. before the addition of 2-isopropoxy-4,4,5,5-tetramethyl-1,3,2-dioxaborolane (25.0 mL, 0.12 mol). The reaction mixture was stirred at −78° C. for 15 minutes then at room temperature for 20 hours. The reaction was quenched with water (200 mL) and then the aqueous layer was extracted with ether (3×200 mL). The combined organic extracts were washed with water (2×200 mL), brine (250 mL), and dried over anhydrous magnesium sulphate. The solution was filtered and solvent removed. The residue was purified by column chromatography over silica using light petroleum:dichloromethane (3:1) as eluent to give 4 (20.4 g, 34%) as a yellow oil.

### (b) 2-[4-(2′-Ethyl-hexyloxy)-2,5-dimethyl-phenyl]-7-nitro-9,9-dipropyl-9H-fluorene (5b)

A mixture of 2-[4-(2′-ethyl-hexyloxy)-2,5-dimethyl-phenyl]-4,4,5,5-tetramethyl-[1,3,2]dioxaborolane 4 (7.0 g, 30 mmol), 2-bromo-7-nitro-9,9-di-n-propyl-9H-fluorene 2 (6.7 g, 20 mmol), aqueous sodium carbonate (2 M, 160 mL), and toluene (240 mL) was deoxygenated with nitrogen for 10 minutes. Compound 2 can be obtained as described in H. Lambert, Part II Thesis, 2003, University of Oxford, UK. Then tetrakis(triphenylphosphine) palladium (0) (0.5 g, 0.4 mmol) was added whilst maintaining a flow of argon over the reaction mixture. The reaction mixture was heated at reflux in the dark for 24 hours. After cooling, aqueous hydrochloric acid (3 M, 100 mL) was added carefully. The aqueous layer was extracted with ether (3×100 mL). The combined organic extracts were washed with water (3×100 mL), brine (100 mL), dried over anhydrous magnesium sulphate, filtered and the solvent was then removed. The residue was purified by column chromatography over silica gel using light petroleum:dichloromethane (3:1) as the eluent followed by recrystallisation from a dichloromethane/methanol mixture to give 5b (6.5 g, 76%), mp 115.0-117.0° C.; (Found: C, 79.71; H, 8.60; N, 2.66. C₃₅H₄₅NO₃ requires C, 79.66; H, 8.59; N, 2.65%); δ_{H} (CDCl₃, 400 MHz) 0.64-0.78 (10H, m), 0.92-1.05 (6H, m), 1.35-1.67 (8H, m), 1.78-1.86 (1H, m), 1.98-2.13 (4H, m), 2.29 (3H, s), 2.31 (3H, s), 3.94 (2H, d, J 5.4), 6.80 (1H, s), 7.12 (1H, s), 7.37 (2H, m), 7.82 (2H, d, J 8) and 8.28 (2H, dd, J 2, J 8).

### (c) 2-[2,5-Bis-acetoxymethyl-4-(2′-ethyl-hexyloxy)-phenyl]-7-nitro-9,9-dipropyl-9H-fluorene (6b)

A mixture of 5b (16.1 g, 31.4 mmol) and N-bromosuccinimide (11.2 g, 62.9 mmol) in carbon tetrachloride (70 mL) was deoxygenated with argon for 10 minutes. 2,2′-Azo-bis(iso-butyronitrile) (2.1 g, 12.6 mmol) was added and reaction mixture was heated at reflux for 4 hours. The reaction mixture was allowed to cool to room temperature, diluted with dichloromethane (30 mL) and passed through a silica plug using dichloromethane as eluent. The solvent was removed and the residue was taken up in glacial acetic acid (70 mL). Sodium acetate (27.8 g, 0.32 mol) was added and the reaction mixture was heated at reflux for 5 hours. After cooling, water (50 mL) was added and the aqueous layer was extracted with ether (3×75 mL). The combined organic extracts were washed with aqueous sodium hydroxide (5% w/v, 50 mL, water (3×150 mL) and a saturated solution of sodium bicarbonate (3×50 mL). The solution was dried over anhydrous magnesium sulphate, filtered and solvent was removed. The residue was purified by flash chromatography over silica using a gradient elution with light petroleum:dichloromethane (1:1-0:1) followed by recrystallisation from a dichloromethane/methanol mixture to give 6b (8.6 g, 42%), mp 103.5-104.5° C.; (Found: C, 72.88; H, 7.68; N, 2.18. C₃₉H₄₉NO₇ requires C, 72.76; H, 7.67; N, 2.18%); δ_{H} (CDCl₃, 400 MHz) 0.68-0.75 (10H, m), 0.94-1.01 (6H, m), 1.34-1.58 (8H, m), 1.75-1.84 (1H, m), 1.98-2.08 (4H, m), 2.27 (3H, s), 2.28 (3H, s), 3.98 (2H, d, J 5.3), 5.04 (2H, s), 5.22 (2H, s), 7.07 (1H, s), 7.38 (3H, m), 7.83 (2H, m), 8.28 (2H, dd, J 2, J 8).

### (d) 2-[2,5-Bis-chloromethyl-4-(2′-ethyl-hexyloxy)-phenyl]-7-nitro-9,9-dipropyl-9H-fluorene (7b)

A mixture of 6b (7.4 g, 11.5 mmol), hydrochloric acid (35%, 160 mL), and 1,4-dioxane (160 mL) was heated at reflux for 18 hours under nitrogen. On cooling, the aqueous layer was separated and extracted with ether (3×50 mL). Combined organic extracts washed with aqueous sodium hydroxide solution (5% w/v, 50 mL), water (3×100 mL), saturated aqueous sodium bicarbonate (50 mL), and brine (50 mL). The organic layer was dried over anhydrous magnesium sulfate, filtered, and then the solvent was removed. The residue was purified by column chromatography over silica using light petroleum:dichloromethane (1:1) as the eluent followed by recrystallisation from a dichloromethane/methanol mixture to give 7b (5.6 g, 83%), mp 84.0-85.0° C.; δ_{H} (CDCl₃, 400 MHz) 0.67-0.79 (10H, m), 0.95-1.06 (6H, m), 1.36-1.77 (8H, m), 1.83-1.89 (1H, m), 2.06-2.14 (4H, m), 4.04 (2H, d, J 5.3), 4.53 (2H, s), 4.72 (2H, s), 7.12 (1H, s), 7.44 (2H, dd, J 8, J 2); 7.57 (1H, s), 7.87 (2H, t, J 7.9), 8.30 (2H, dd, J 8, J 2); Exact mass 595.2602. C₃₅H₄₃Cl₂NO₃ requires 595.2620.

### (e) Poly{2-[2-(7-nitro-9,9-dipropyl-9H-fluorene)]-5-(2′-ethyl-hexyloxy)-1,4-phenylenevinylene} (8b)

Potassium tert-butoxide (0.66 g, 5.86 mmol) in dry tetrahydrofuran (58.6 mL) was added to a stirred solution of 7b (0.7 g, 1.17 mmol) in dry tetrahydrofuran (23.4 mL) at room temperature under nitrogen. The reaction mixture was stirred in dark for 3.5 hours. The solution was poured into ice-cold methanol (100 mL), centrifuged (4500 rpm, 5 minutes), and the supernatant was removed. The residue was taken up in tetrahydrofuran (50 mL), filtered through a cotton wool plug and then poured onto ice-cold methanol (40 mL). The polymer was collected after centrifugation and the process was repeated once more. The residue was dried under vacuum for 16 hours to give 8b (284 mg, 46%); νₘₐₓ (film, KBr disc)/cm⁻¹ 969 (C═C—H trans), 1523 (NO₂), 1338 (NO₂); λₘₐₓ (film)/nm 204, 250 sh, 356 and 422 sh; M̅_{w}=3.2×10⁵, M̅ₙ=0.5×10⁵ and PD=7.0.

### Example 2

### Measurement of Photophysical and Device Properties

The photophysical properties and device performance of 8a and 8b were measured and the results are summarised in Table 1. From the PLQY measurements it is clear that the NO₂ group on 8b is quenching the luminescence by a factor of eight relative to polymer 8a.

TABLE 1
Photophysical and device properties of polymers

| | | | Device: | | |
|---|---|---|---|---|---|
| | | | ITO/PEDOT:PSS/Polymer/Al | | |
| | PLQY (%) | | V_{OC} | I_{SC} | Efficiency |
| Polymer | ITO | Solution | (V) | (A/cm²) | (%) |
| 8a | 6.4 | 19.1 | 1.13 | −5.1E−07 | 1.5E−04 |
| (Comparative) | | | | | |
| 8b | 0.8 | 2.8 | 0.84 | −1.8E−06 | 3.1E−04 |
| (Invention) | | | | | |

Neat single-layer devices were prepared with the architecture ITO/PEDOT:PSS/polymer/Al and tested for each of the two polymers. As can be seen above, polymer 8b in accordance with the invention displays a photovoltaic effect.

Without wishing to be bound by theory, the lower PLQY of 8b compared with 8a could arise from photoinduced intramolecular charge separation. To investigate this further, light-induced electron spin resonance (LESR) experiments were performed. For 8a, the LESR signal was barely detectable, whereas for 8b a clear signal (in the region of ten times stronger for equivalent experimental conditions) was seen, further suggesting that light-induced charge separation does occur.

1. A photovoltaic cell comprising a photovoltaic layer comprising a conjugated polymer comprising monomer units of the formula (I): 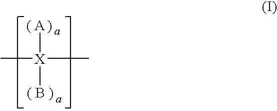
wherein:
X is selected from C₆₋₁₄ arylene, C₆₋₁₄ arylene-vinylene and C₆₋₁₄ arylene-acetylene units;
each A represents a group of formula -(L)₁-EWG wherein EWG is an electron-withdrawing group;
a is 1, 2 or 3;
1 is zero or an integer of from 1 to 10;
L is a spacer group selected from C₆₋₁₄ arylene, (C₆₋₁₄ arylene)-vinylene, (C₆₋₁₄ arylene)-acetylene, 5- to 10-membered heteroarylene, (5- to 10-membered heteroarylene)-vinylene, and (5- to 10-membered heteroarylene)-acetylene groups, wherein the arylene and heteroarylene moieties are unsubstituted or substituted by one or more groups selected from C₁₋₁₀ alkyl, C₁₋₁₀ alkoxy and EWG groups defined above;
each B represents a group of formula -(L′)_{1′}-EDG wherein EDG is an electron-donating group;
b is 1, 2 or 3;
1′ is zero or an integer of from 1 to 10;
L′ is a spacer group selected from C₆₋₁₄ arylene, (C₆₋₁₄ arylene)-vinylene, (C₆₋₁₄ arylene)-acetylene, 5- to 10-membered heteroarylene, (5- to 10-membered heteroarylene)-vinylene, and (5- to 10-membered heteroarylene)-acetylene groups, wherein the arylene and heteroarylene moieties are unsubstituted or substituted by one or more groups selected from C₁₋₁₀ alkyl, C₁₋₁₀ alkoxy and EDG groups defined above;
when 1 is greater than zero, EWG is attached to an arylene, heteroarylene, vinylene or acetylene moiety of L;
when 1′ is greater than zero, EDG is attached to an arylene or heteroarylene moiety of L′; and
1 and 1′ are not both zero.

2. A photovoltaic cell as claimed in claim 1 wherein the electron-withdrawing groups, which are the same or different if a is greater than one, are selected from nitro, cyano, ketone, sulfone, sulfoxide, halo(C₁₋₆ alkyl), and halo(C₆₋₁₄ aryl) groups.

3. A photovoltaic cell as claimed in claim 1 wherein the electron-donating groups, which are the same or different if b is greater than one, are selected from C₁₋₁₀ alkyl, C₁₋₁₀ alkoxy, amino, C₁₋₁₀ alkylamino and di(C₁₋₁₀ alkyl)amino groups, wherein the C₁₋₁₀ alkyl and C₁₋₁₀ alkoxy groups and the C₁₋₁₀ alkyl moieties of the C₁₋₁₀ alkylamino and di(C₁₋₁₀ alkyl)amino groups are unsubstituted or substituted by one, two or three groups selected from C₁₋₄ alkyl groups and C₁₋₄ alkoxy groups.

4. A photovoltaic cell as claimed in claim 1 wherein a is 1 or 2, and/or b is 1 or 2.

5. A photovoltaic cell as claimed in claim 1 wherein 1 is zero or an integer of from 1 to 5, and/or 1′ is zero or an integer of from 1 to 5.

6. A photovoltaic cell as claimed in claim 1 wherein each L, which is the same or different if 1 is greater than 1, is selected from C₆₋₁₄ arylene, (C₆₋₁₄ arylene)-vinylene and (C₆₋₁₄ arylene)-acetylene groups, wherein the C₆₋₁₄ arylene groups and the C₆₋₁₄ arylene moieties of the (C₆₋₁₄ arylene)-vinylene and (C₆₋₁₄ arylene)-acetylene groups are unsubstituted or substituted with one or two groups selected from C₁₋₁₀ alkyl.

7. A photovoltaic cell as claimed in claim 1 wherein each L′, which is the same or different if 1′ is greater than 1, is selected from C₆₋₁₄ arylene, (C₆₋₁₄ arylene)-vinylene and (C₆₋₁₄ arylene)-acetylene groups, wherein the C₆₋₁₄ arylene groups and the C₆₋₁₄ arylene moieties of the (C₆₋₁₄ arylene)-vinylene and (C₆₋₁₄ arylene)-acetylene groups are unsubstituted or substituted with one or two groups selected from C₁₋₁₀ alkyl and C₁₋₁₀ alkoxy.

8. A photovoltaic cell as claimed in claim 1 wherein the conjugated polymer comprises monomer units of one or more of formulae (IIA), (IIB) and (IIC): 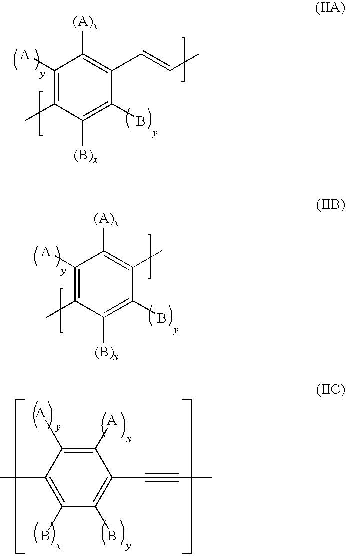
wherein A, B, L, L′, 1, 1′, EWG and EDG are as defined in claim 1, each x is zero or one, and each y is zero or one provided that at least one A group and at least one B group are present.

9. A photovoltaic cell as claimed in claim 8 wherein either x is 1 and y is zero, or x is zero and y is 1.

10. A photovoltaic cell as claimed in claim 1 wherein the conjugated polymer comprises monomer units of one or more of formulae (IIIA), (IIIB) and (IIIC): 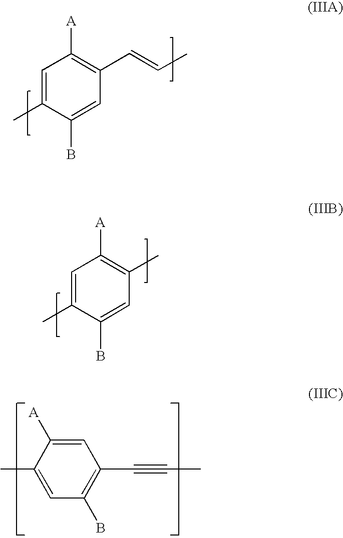
wherein A, B, L, L′, 1, 1′, EWG and EDG are as defined in claim 1.

11. Use of a conjugated polymer comprising monomer units of formula (I) as a photovoltaic material in a photovoltaic cell: 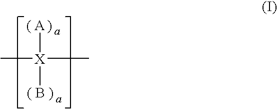
wherein:
X is selected from C₆₋₁₄ arylene, C₆₋₁₄ arylene-vinylene and C₆₋₁₄ arylene-acetylene units;
each A represents a group of formula -(L)₁-EWG wherein EWG is an electron-withdrawing group;
a is 1, 2 or 3;
1 is zero or an integer of from 1 to 10;
L is a spacer group selected from C₆₋₁₄ arylene, (C₆₋₁₄ arylene)-vinylene, (C₆₋₁₄ arylene)-acetylene, 5- to 10-membered heteroarylene, (5- to 10-membered heteroarylene)-vinylene, and (5- to 10-membered heteroarylene)-acetylene groups, wherein the arylene and heteroarylene moieties are unsubstituted or substituted by one or more groups selected from C₁₋₁₀ alkyl, C₁₋₁₀ alkoxy and EWG groups defined above;
each B represents a group of formula -(L′)_{1′}-EDG wherein EDG is an electron-donating group;
b is 1, 2 or 3;
1′ is zero or an integer of from 1 to 10;
L′ is a spacer group selected from C₆₋₁₄ arylene, (C₆₋₁₄ arylene)-vinylene, (C₆₋₁₄ arylene)-acetylene, 5- to 10-membered heteroarylene, (5- to 10-membered heteroarylene)-vinylene, and (5- to 10-membered heteroarylene)-acetylene groups, wherein the arylene and heteroarylene moieties are unsubstituted or substituted by one or more groups selected from C₁₋₁₀ alkyl, C₁₋₁₀ alkoxy and EDG groups defined above;
when 1 is greater than zero, EWG is attached to an arylene, heteroarylene, vinylene or acetylene moiety of L;
when 1′ is greater than zero, EDG is attached to an arylene or heteroarylene moiety of L′; and
1 and 1′ are not both zero.

12. (canceled)
